(19) United States
(12) Patent Application Publication
(10) Pub. No.: US 2018/0102160 A1
(43) Pub. Date: Apr. 12, 2018

(54) DDR Controller for Thyristor Memory Cell Arrays

(71) Applicant: Kilopass Technology, Inc., San Jose, CA (US)

(72) Inventors: Adrian E. Ong, Pleasanton, CA (US); Bruce L. Bateman, Fremont, CA (US); Charlie Cheng, Los Altos, CA (US)

(21) Appl. No.: 15/729,627

(22) Filed: Oct. 10, 2017

Related U.S. Application Data
(60) Provisional application No. 62/405,815, filed on Oct. 7, 2016.

(51) Int. Cl. G11C 11/39; G11C 11/4076

(52) U.S. Cl. CPC G11C 11/39; G11C 11/4076

(57) ABSTRACT

A vertical thyristor memory cell array with each of the thyristor memory cells connected to bit and word lines, the bit lines are connected to the inputs of multiplexers which are connected to sense amplifiers, is adaptable to LPDDR4 requirements. The lack of refresh operations for the vertical thyristor memory cell array is not apparent to a LPDDR4 memory controller so that a standard or an LPDDR4 memory controller which omits refresh operations and specifically adapted for a vertical thyristor memory can control the transfer of data to and from the plurality of vertical thyristor memory integrated circuits.

### CROSS-REFERENCE TO RELATED APPLICATIONS

This patent application claims priority from U.S. Provisional Patent Application No. 62/405,815, entitled, “DDR Controller for Thyristor Memory Cell,” and filed Oct. 7, 2016.

### BACKGROUND OF THE INVENTION

This invention is related to integrated circuit devices and in particular to random access semiconductor memories, including dynamic random access memories (DRAMs).

A DRAM is a type of random access memory that typically stores each bit of data in a separate capacitor coupled to a transistor within the integrated circuit. Lithographic scaling and process enhancements usually quadruple number of bits of storage in a DRAM integrated circuit about every three years, sometimes referred to as “Moore's Law.” However, the individual memory cells are now so small that maintaining the capacitance of each cell, as well as reducing charge leakage from the cell, may significantly inhibit continual size reductions.

What is needed is a memory cell that is smaller than the conventional one-transistor, one-capacitor cell, that is readily scalable below 20 nm design rules, that is compatible with standard bulk silicon processing technology, and that consumes lower power, both statically and dynamically. One replacement for the conventional one-transistor, one-capacitor cell is a vertically arranged thyristor, or semiconductor-controlled rectifier (SCR), memory cell. Examples of vertically arranged thyristor, or vertical layer thyristor (VLT), memory cells are described in U.S. Pat. No. 9,564,199, which issued on Feb. 7, 2017 and assigned to the present assignee, and related cases.

The present invention utilizes such VLT memory cell arrays. But there is still the problem of reading the bit information stored in a memory cell array and of writing bit information into a memory cell array for storage. For DRAM memory cell arrays, there is a DDR SDRAM (Double Data Rate Synchronous DRAM) standard, or more precisely, a series of standards, developed by JEDEC (Joint Electron Device Engineering Council), under which bits are transferred to and from DRAM integrated circuits at high speed. The DDR SRAM (or DDR for short) standard also defines high speed transfer of bits to and from memory modules of DRAM integrated circuits along the buses of a computer system.

A thyristor-based memory integrated circuit, which includes, or is based on, a VLT memory can be designed to be compatible with DDR standards, specifically LPDDR4. It is desirable that a VLT memory integrated circuit be designed to interface with a standard DDR controller or with a customized DDR controller to adapt to the advantages of a VLT memory.

### BRIEF SUMMARY OF THE INVENTION

The present invention provides for a memory system comprising a plurality of memory integrated circuits and a memory controller. Each memory integrated circuit has a plurality of parallel bit lines in a first direction and a plurality of parallel word lines in a second direction perpendicular to the first direction; a plurality of thyristor memory cells, each thyristor memory cell at the intersection of a bit line and a word line, and formed by semiconductor layers vertically arranged in a semiconductor substrate, the semiconductor layers doped with alternating P and N-type dopants, a top semiconductor layer connected to a bit or word lines, a bottom semiconductor layer connected to the other of the bit or word lines; and each of the bit lines connected to an input of a multiplexer, the output of the multiplexer coupled to a sense amplifier for reading the value of a bit stored in a selected thyristor memory cell. The memory controller controls the transfer of data to and from the plurality of memory integrated circuits according to DDR requirements whereby the memory system can transfer data at high-speed. The DDR requirements are more specifically LPDDR4 requirements.

The present invention also provides for a memory controller for a memory system having a plurality of memory integrated circuits. Each memory integrated circuit has a plurality of thyristor memory cells, each thyristor memory cell at the intersection of a bit line and a word line, and formed by semiconductor layers vertically arranged in a semiconductor substrate, the semiconductor layers doped with alternating P and N-type dopants, a top semiconductor layer connected to a bit or word lines, a bottom semiconductor layer connected to the other of the bit or word lines, and each of the bit lines connected to an input of a multiplexer, the output of the multiplexer coupled to a sense amplifier for reading the value of a bit stored in a selected thyristor memory cell. The memory controller controls the transfer of data to and from the plurality of memory integrated circuits according to DDR requirements, the memory controller operating with no logic states for refresh operations in the plurality of memory integrated circuits.

Other objects, features, and advantages of the present invention will become apparent upon consideration of the following detailed description and the accompanying drawings, in which like reference designations represent like features throughout the figures.

### BRIEF DESCRIPTION OF THE DRAWINGS

FIG. 1 shows a functional block diagram of a VLT memory cell integrated circuit of one embodiment of the present invention.

FIG. 2 illustrates the connection of bit lines to a multiplexer, the output of which is connected to a sense amplifier (and latch) in a VLT memory array.

FIG. 3 is an illustrative comparison between a conventional DRAM bank and a VLT memory array bank according to one embodiment of present invention.

FIG. 4 shows an arrangement of VLT memory array MATs in an embodiment of the present claimed invention.

FIG. 5 shows the bit line connections between the VLT memory array MATs.

FIG. 6 shows a representation of a DDR controllers in a computer system memory.

FIG. 7 is a representation of the various states of an LPDDR4 memory controller.

FIG. 8 is a representation of the states of an LPDDR4 memory controller specifically adapted for a VLT memory.

### DETAILED DESCRIPTION OF THE INVENTION

In order to show VLT memory arrays can be adapted to DDR standard requirements, it may be helpful to review how conventional DRAMs operate under the DDR standard. In this particular example the version of the DDR standard is LPDDR4 (Low-Power Double Data Rate 4), which represents a low-power version of the fourth iteration of DDR SDRAM standard.

DRAM and DDR Operations

Many aspects of DRAM operation derive from the characteristics of a capacitive storage cell. The leakiness of the capacitor results in a need for refresh operations to recharge the cell capacitor, and the fundamental way the storage cell is read affects other aspects of how the DRAM memory is organized. Charge sharing is used to sense the bit value of a memory cell. The bit line is first pre-charged to a voltage between a logic 1 and a logic 0, generally V_{DD}/2. The cell is then selected by turning on the access transistor of the cell so charge moves between the bit line and the cell. If the bit line is at a higher voltage than the cell, then charge moves out of the cell onto the bit line; if the bit line is at a lower voltage than the cell, then charge moves from the bit line into the cell. A charge transfer changes the voltage on the bit line, which is sensed and latched as the read value of the cell. However, a loss or gain of charge in the storage capacitor alters the original charge on the node, so that the read process is destructive. Therefore, after each read operation, the original charge levels must be restored through a write-back operation.

Two ways of looking at a DRAM are: logically, where physical details are abstracted; and physically, where silicon array characteristics are considered. The logical arrangement should correspond to the physical arrangement. For example, an LPDDR4 memory chip may have a capacity for 8 Gb of storage, implemented as two independent channels of 4 Gb each. A channel may have eight banks of memory. Each bank may have a size of 512 Mb arranged as 32K pages of 16K bits each. A page is a fixed-length contiguous block of virtual memory, described by a single entry in a page table. It is the smallest unit of data for memory management in a virtual memory operating system.

A full LPDDR4 memory integrated circuit consists of two high-level elements: the memory cell array and the DDR interface. Some operations affect the memory cell array; others affect the interface. Activity between the interface and the array may take place in the background while other activity is present between the interface and the external system.

LPDDR4 functionality fundamentally consists of four basic operations: activate, read, write, and pre-charge. Variations on these (like burst read/write, auto-pre-charge, and so forth) may result in a longer list of commands but do not change the technology. These instructions are supplemented with maintenance operations, such as refresh, training, and mode register operations for a complex set of operational commands.

The basic operations may be summarized as follows: An Activate operation causes a page of memory to be opened by selecting the appropriate word lines in the array. (A page is a fixed-length contiguous block of virtual memory, described by a single entry in the page table. It is the smallest unit of data for memory management in a virtual memory operating system and hence the smallest unit of data to move into, or from memory, in a computer system.) The contents of the page are sensed and latched; the page is left open either for write-back (in the case of a read operation) or write (in what is effectively a read-modify-write). A Read operation starts the read-out sequence. Each burst group is loaded from the sense amplifier latches into the DDR register, and then the DDR register is read sequentially, one 16-bit word at a time. Write-back occurs in the background via the bit line sense amplifiers via the still-open page. A Write operation loads data into a DDR register, one 16-bit word at a time. The contents are then loaded into the Shadow Register for writing into the array (via the still-open page). While they are written, a new 256-bit value can be loaded into the DDR register for a subsequent write, if desired. A Pre-charge prepares the array for the next operation after the final burst group has been read or written. In the case of a writing operation, a write-recovery delay is needed to ensure that the last burst group is successfully written to the array before proceeding. The opened page is closed, which allows the bit lines to float and be charged back to the VDD/2 level.

Only the Activate operation involves memory array sensing; the Read operation involves transfer of data between the latched sensed data and the DDR register and the readout of the DDR register.

Two ways of looking at a DRAM are: logically, where physical details are abstracted; and physically, where silicon array characteristics are considered. The logical arrangement should correspond to the physical arrangement.

A DDR register is the main interface between the outside system and the memory array. When reading, memory cell array data is loaded first into the DDR register; when writing, the desired data is first written from outside into the register. Because reading the traditional DRAM cell array contents is destructive, each read operation must be followed by a write-back operation that restores the original values into the cells. After reading, the DDR register contents are copied to a Shadow Register. While the contents of the DDR register are read by the outside system, the Shadow Register implements the write-back to restore the values on the selected page. Likewise, when writing to the array, the value in the DDR register is transferred to the Shadow Register for writing. While that value is being written, a new value can be loaded into the DDR register.

Reading a page of memory involves a sequence of events that resemble two nested software DO-loops. Each page is divided into burst groups of 256 bits each. Thus, a single bank's 16K-bit page has 64 burst groups. A full page is read by sequentially reading each burst group; this resembles the outer DO loop. Each burst group is loaded into the 256-bit DDR register. That register is divided into 16 16-bit words, and the contents are read out by sequentially, delivering each 16-bit word on each clock edge. This behaves as the inner DO loop. The row address signals, entered as the RAS, select the page. The column address signals, or CAS, select both the burst group and set the starting word to be read from the DDR register, since one doesn't need to start reading at the left side of the DDR register.

This sequence of reading values out of (or writing values into) the DDR register that proceeds while the Shadow Register is implementing either write-back of the values just read or writing of the values previously loaded into the DDR register.

Timing may be complex, depending on the desired sequence of operations. If a read in one bank is followed by a read in a different bank, timing requirements are eased, since there is no need to wait for write-back and pre-charge in the original bank before reading from the next bank. The toughest timing requirements involve successive reads and writes from the same bank.

While a memory bank would appear logically to be a single array with 32K rows and 16K columns, it's not physically possible to build such an array given known techniques. Drivers that select pages have a limited drive capacity; thus, only a limited number of select transistors can be driven without performance degrading below specification. Sense amplifiers can support only a limited number of storage cells. With too many cells, the change in voltage due to charge sharing becomes too small and is swamped by noise.

Therefore, each memory implementation results in some maximum physical array that can be built in order to guarantee a manufacturable memory that is fast and reliable. This maximum array is referred to as a memory array tile, or MAT. Each MAT is a self-contained array with its own word line and bit line decoding and sense amps. The memory is formed by a replication of a MAT in some arrangement.

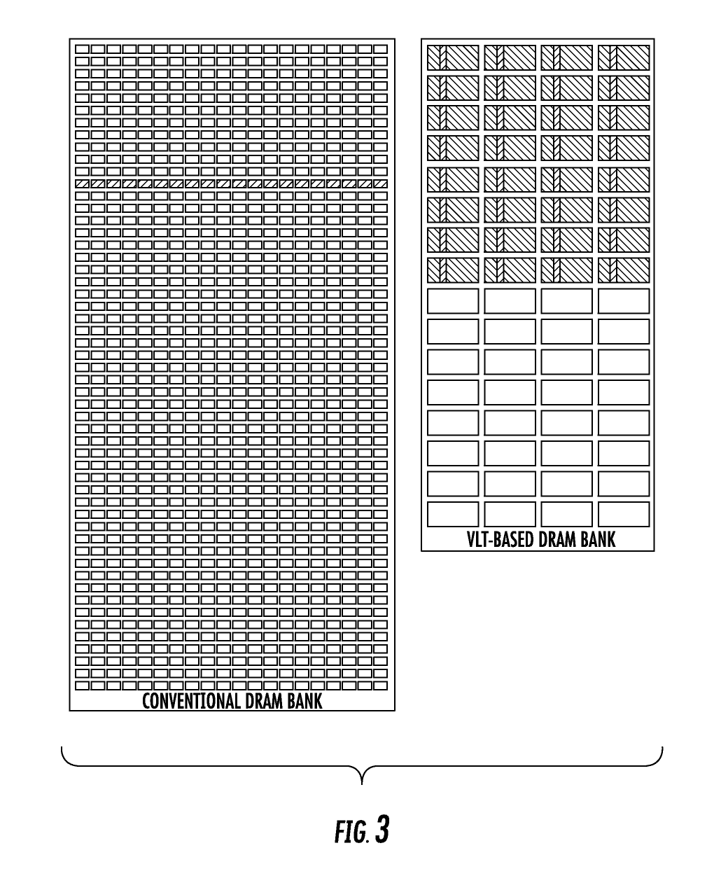

One example MAT from a conventional DRAM array at the 2X-nm process (2X-nm process is a shorthand designation of semiconductor processes with a range of 20 to 29 nm critical dimensions) node is sized at 1024 bitlines and 620 wordlines. This non-power-of-2 sizing poses some decoding challenges and may only partially use the last MATs. A bank with this size MAT is then built by creating an array of MATs that is 16 wide and 53 deep, for a total of 848 MATs, as shown by the left hand drawing in FIG. 3. A full page incorporates a row of MATs: when a page is opened, the corresponding word lines are activated in all of the MATs in the same row, as represented by a row of cross-hatched MATs in left hand drawing in FIG. 3.

Vertical Thyristor Memory Cell Arrays

In an embodiment of the present invention, a thyristor-based memory can be used in place of the conventional one-capacitor, one transistor DRAM. In particular, vertical layer thyristor (VLT) memory cell arrays are designed to be compatible with LPDDR4 (Low-Power Double Data Rate 4) DRAM memory. Banks of VLT memory can mimic banks of conventional DRAM, with similar, equivalent, or compatible timing and a VLT memory may even interface to a standard DDR controller or to a customized DDR controller.

An array of VLT thyristor memory bit cells are arranged in a cross-point grid and interconnected by metal conductors and buried doped layers which form row and column lines. In one embodiment of the present invention, each memory cell thyristor is formed by a PNPN stack built over a P-well in a semiconductor substrate with an anode connected to a row line and a cathode connected to a column line. The bottom N layers (i.e., the cathode) of a column of memory cell thyristors are connected together by a buried bit line between deep-trench isolation regions which separate the memory cell columns. Shallow trench isolation (STI) regions separate the memory cell rows. In one embodiment, the bottom of the STI regions is made of tungsten so that a buried bit line is formed by alternating sections of N regions and tungsten. Tungsten is relatively resistive so that the voltage along the line is maintained by tapping from a copper metal 1 layer. Copper permits a much longer bit line to be supported than is possible with conventional DRAM. The tungsten between the bottom N regions removes minority carriers, such as holes, from a memory cell that may otherwise disturb adjacent memory cells.

It should be noted that the VLT memory cells can also be constructed having row and column connections reversed with corresponding modifications well understood by semiconductor circuit designers. Furthermore, through the drawings show rows as horizontal and columns as vertical, the words, row and column, should be understood in the general sense of a first direction and a perpendicular second direction.

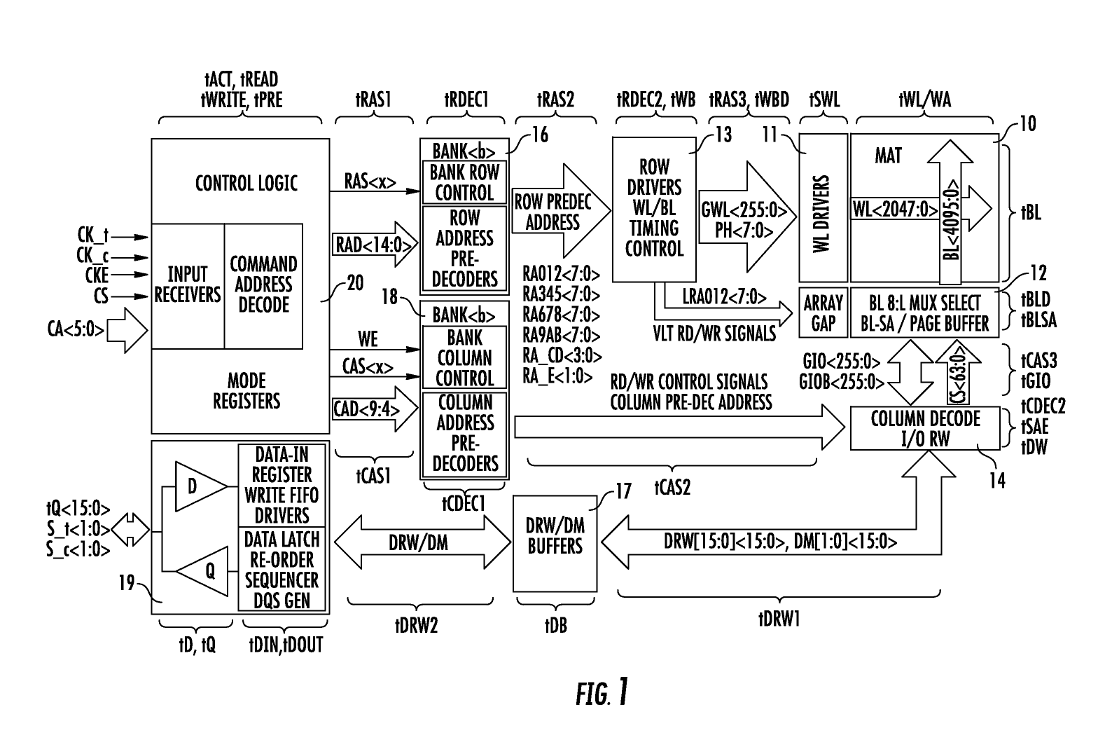

With VLT memory cells a RAM (Random Access Memory) integrated circuit can be constructed as a replacement for a DRAM integrated circuit. As shown in FIG. 1, the general architecture of a VLT memory chip has many features of a conventional DRAM integrated circuit. Around a memory cell array 10 there are word line drivers 11 which respond to row driver timing control block 13. The block 13 in turn is controlled by signals from bank row and row address pre-coder block 16, which receives row address and control signals from control logic 20. Bit lines of the memory cell array 10 respond to bit line multiplexer/sense amplifier block 12, and column decoder and read-write input/output block 14. The column decoder and read-write input/output block 14 receives data signals read from the array 10 through the to bit line multiplexer/sense amplifier block 12, and transmits data signals to be written into the array 10 through the bit line multiplexer/sense amplifier block 12, in response to Read/Write control signals and column pre-decoded signals from bank column control and column address pre-decoder block 18. Both the bank row and row address pre-coder block 16 and the bank column control and column address pre-decoder block 18 receive row address signals and column address signals from a control logic block 20 which receives external clock and timing signals. Data signals are received from external sources by register write driver and data latch block 19, passed through buffer block 17 onto the column decoder and read-write input/output block 14 (and the bit line multiplexer/sense amplifier block 12) for writing into the array 10. A reverse path is followed for a read operation: through the bit line multiplexer/sense amplifier block 12, data from the array 10 are sent through the column decoder and read-write input/output block 14 to the buffer block 17 and on to write driver and data latch block 19 for external transmittal.

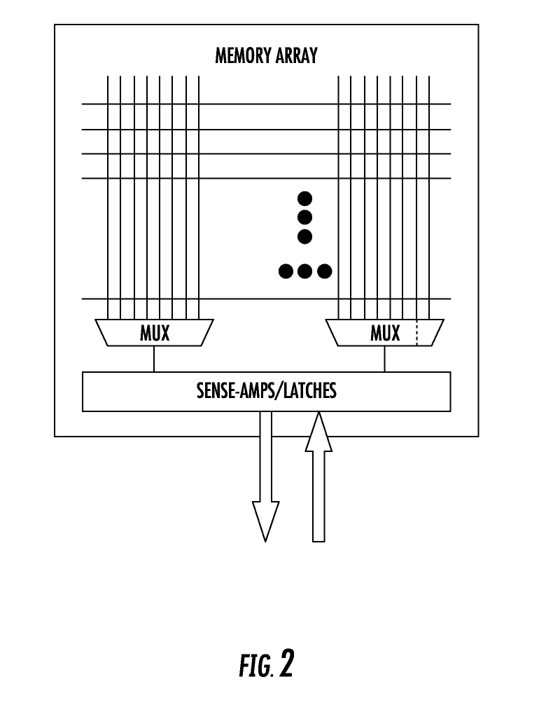

A significant difference from a conventional DRAM integrated circuit, however, is that the memory cells in the array 10 do not require refresh operations, which are intimately woven into DRAM operations. Whether the DRAM memory is idle or being accessed, refresh events must occur to prevent loss of data. During a read operation all bit lines of a conventional DRAM must be read for write-back purposes, i.e., all the bit lines are read so that the read values are written back into the read memory cells. On the other hand, a read operation in a VLT memory cell array is not destructive and no write-back is needed. Therefore the VLT bit cells can share sense amps, as represented in FIG. 2 in which a plurality of bit lines feed into a multiplexer and the output of the multiplexer is connected to the input of a sense amplifier. In a reverse direction, the outputs of latches are connected to the inputs of demultiplexers (multiplexers operating in the opposite direction), the outputs of which are connected to the bit lines of VLT memory cell array. In a write operation data in a latch is sent over a bit line selected by the demultiplexer to a VLT memory cell.

The sensing mechanism for thyristor memory cells arrays does not rely on charge sharing so that the VLT sense amplifiers can support longer bit lines than the DRAM sense amplifiers. Therefore, the VLT technology can support a MAT that is 2K (2¹¹) bits wide and 4K (2¹²) bits deep, or 8M (2²³) bits in total—much larger than a conventional MAT. A memory made of fewer tiles has less overhead than one made with more tiles. In one embodiment, the array efficiency of a basic VLT array is 77% as compared to 64% for conventional DRAM fabricated on the same 2X-nm process technology. With a larger MAT, an LPDDR4 bank can be built with fewer MATs. From a pure bit-count standpoint, a VLT-based bank contains 64 MATs, as shown by the right hand drawings of FIG. 3 in comparison to a conventional arrangement of 848 smaller MATs.

Page access differs between a conventional DRAM, which selects all MATs in a row (shown in the cross-hatched MAT row in left hand drawing of FIG. 3), and a VLT memory, which selects from within a 4×8 block of MATs (shown by the cross-hatched MATs in the top half of the right hand drawing of FIG. 3).

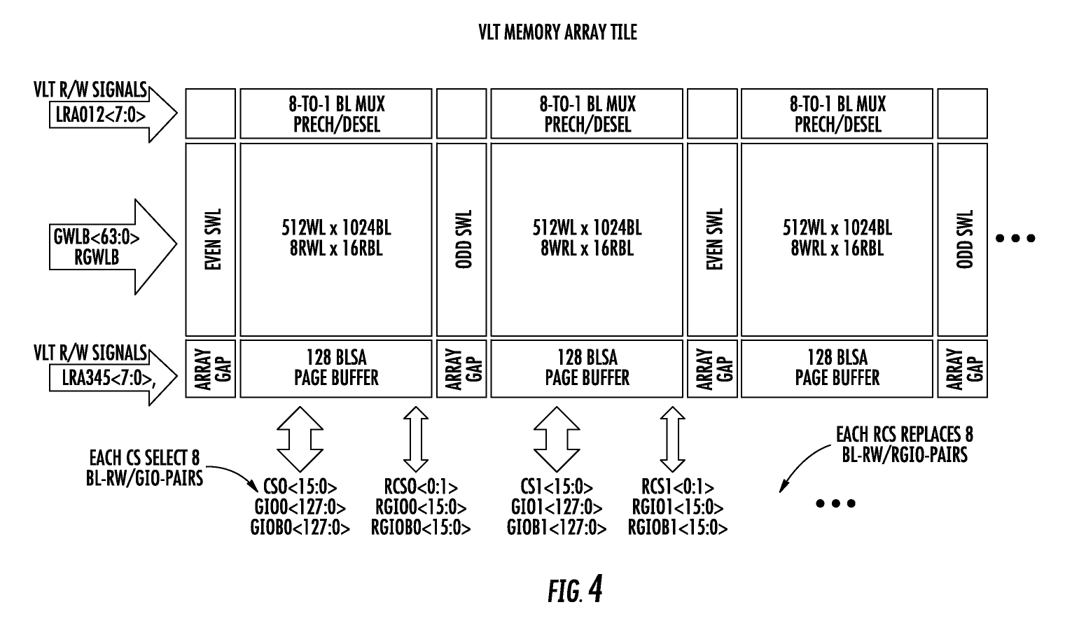

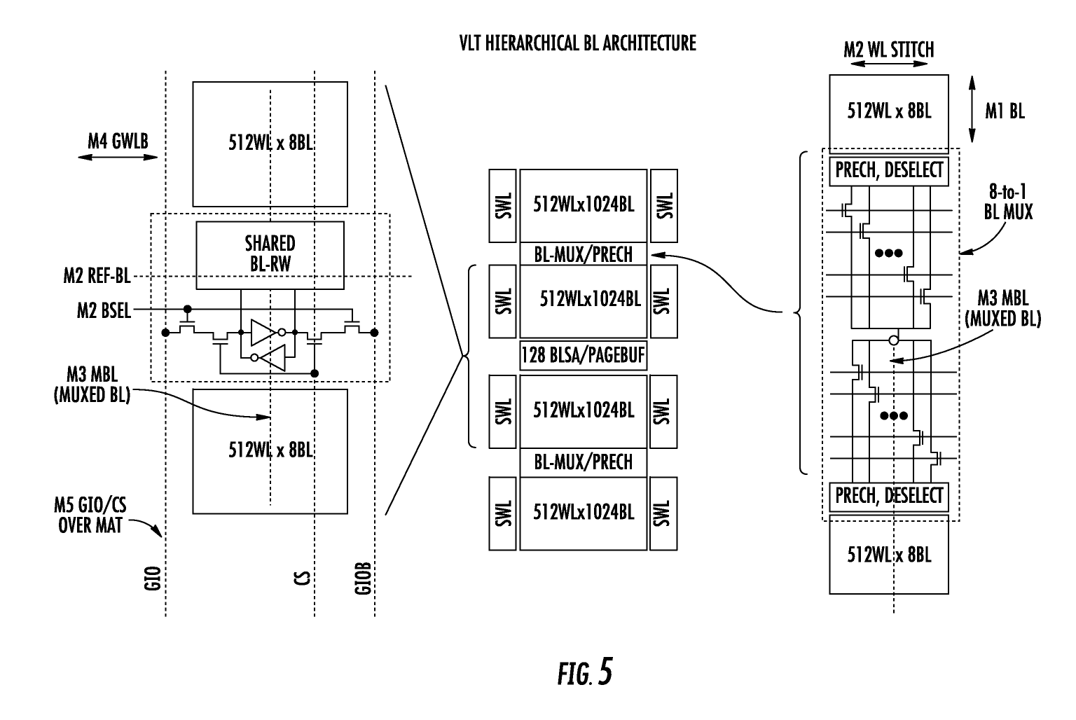

An effective arrangement of the 64 MATs has each MAT with 512 sense amplifiers supporting the 4K bit lines; each sense amplifier has a multiplexer to select between 8 bit lines, as shown in detail in FIGS. 4 and 5. FIG. 4 shows a partial VLT MAT. The MAT is divided into 4 parts, 3 of which are shown in the drawing. The fourth part lies to the right of the 3 parts shown in FIG. 4. Each part has 512×1024 memory cells with (segment) word lines (SWL) horizontal and bit lines vertical in the drawing. The bit lines are divided into sets of 8 bit lines each with each set of bit lines connected to the inputs of a multiplexer which has its output connected to a sense amplifier. Hence each part has 128 multiplexers and sense amplifiers to handle 1024 bit lines with the result that each MAT can read or write 4×1024 bits at a time. Each multiplexer selects a bit line based on the CAS (Column Address Select) address.

FIG. 5 shows how the multiple VLT MATs are coupled vertically (with respect to the drawing), as illustrated by the center drawing. As shown in the right figure details, each set of 8 bit lines in a MAT part is received by an 8-to-1 multiplexer, the output of which is connected to a multiplexed bit line (MBL). At locations in a column of 8 bit lines, one of 128 bit line sense amplifiers/page buffers latches a bit of information to or from a selected memory cell received through the MBL. This is shown on the right drawing of FIG. 5. The latched bit is placed onto global input/output (GIO) lines, GIO and GIOB. These complementary bit lines provide the pathways to and from the MAT.

In operation, for each page selected one eighth of the bit lines in each MAT are selected, in contrast with the conventional DRAM implementation, where all bit lines are selected. This more efficient use of sense amplifiers would not be possible in a conventional DRAM, where all bit lines must be read for write-back purposes. Because the VLT read is not destructive, no write-back is needed, and therefore bit cells can share sense amps.

Given the flexibility of a VLT MAT, the physical arrangement of MATs may be decoupled from the logical arrangement. Any number of physical arrangements may be possible so long as the busses are routed properly. In one example shown in FIG. 2, a bank is built as a 4 by 16 array of MATs while delivering data that logically matches the conventional LPDDR4 memory.

DDR Controller for Vertical Thyristor Memory

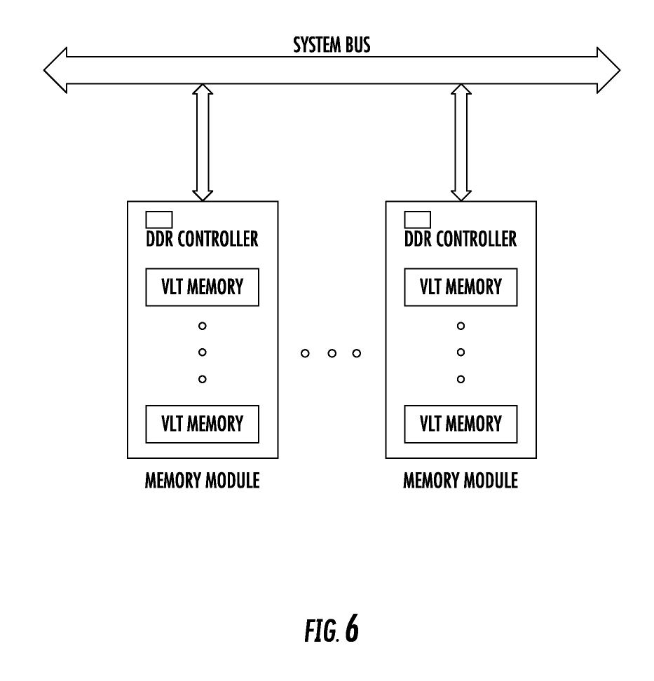

FIG. 6 is a representation of a computer system memory unit which has memory modules each holding a plurality of DRAM memory integrated circuits into which data is transferred in a write operation or from which data is retrieved in a read operation. To help coordinate DDR memory operations, the memory modules also have a DDR memory controller integrated circuit. For LPDDR4 operations, the DDR controller and the DRAM memory integrated circuits conform to LPDDR4 requirements.

As noted above, VLT memory cell integrated circuits can replace conventional DRAM integrated circuits. To the outside, all LPDDR4 operations for the VLT memory behave as they would for a conventional DRAM memory. However, internal operations vary, since, for example, write-back and pre-charge may not be required. However, any such internal difference may not be evident to the DDR controller since the internal memory logic maps all of the operations to their VLT equivalents, with all timing requirements being met. Stated differently, with a standard DDR, e.g., LPDDR4, controller, some steps, operations, and functions that are not needed or used by VLT memory may be skipped, bypassed, covered, or ignored. The rest of the system will treat the VLT memory like conventional DRAM, with minimal, or no, change required.

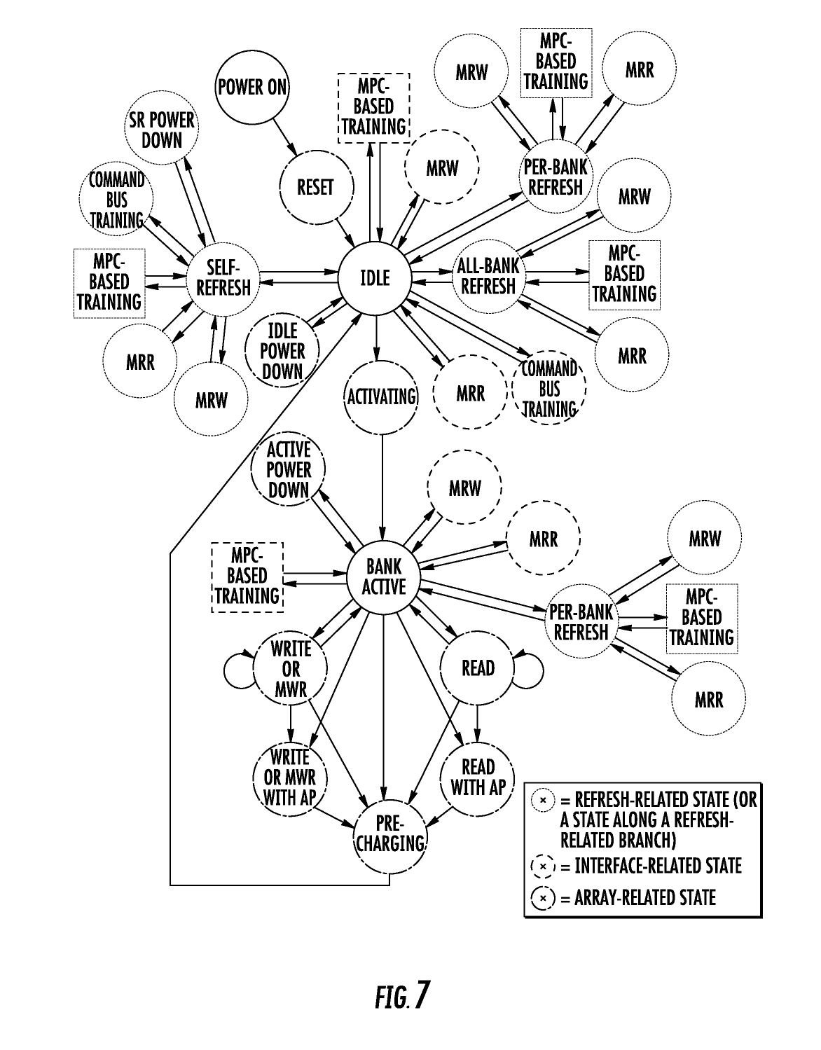

On the other hand, a benefit of the VLT bit cell is that it requires no refresh, while refresh is intimately woven into DRAM operation. Whether the DRAM memory is idle or being accessed, refresh events must occur to prevent loss of data. The state machine for an LPDDR4 controller illustrates the impact of refresh on operation, such as illustrated in FIG. 7. Refresh operations related states are enclosed by small dotted line. As noted at the right-hand bottom of the drawing, interface-related states are enclosed by a large dotted line and array-related states are enclosed by a line and dot combination. The basic states are Idle, Bank Active, and Pre-Charging, and the transitional state of Activating. Many of the states are self-explanatory, and for completeness' sake, MPC stands for multi-purpose command, SR for self-refresh, MRW for mode register write, MRR for mode register read and AP for auto-precharge. LPDDR4 also requires training states in which certain parameters are set before operations begin.

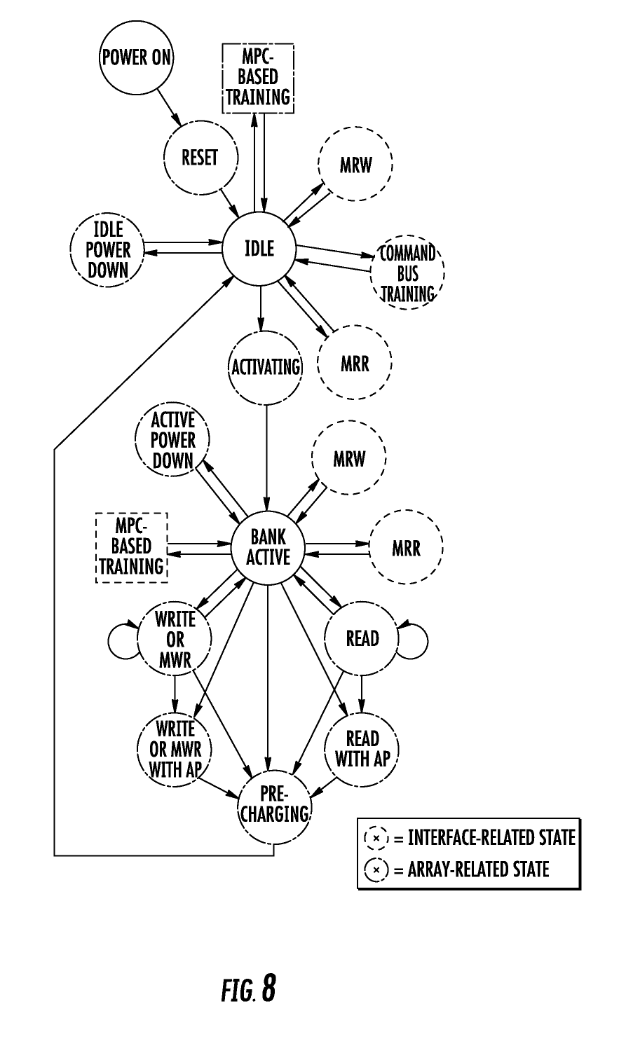

In an embodiment of the present invention, an LPDDR4 controller with a simplified state machine, having refresh-related and, if desired, other unnecessary circuitry removed, may be implemented. All states relating to refresh (or branches based on refresh) are rendered redundant for VLT memory are removed. Such a simplified state machine for a modified controller is shown in FIG. 8. A large reduction in the number of states is evident by a comparison with the state machine of FIG. 7. Thus a VLT-based memory may also use a customized DDR controller that has been adapted, modified, or optimized to accommodate non-existent states. The latter option will occupy less silicon and consume less power. Whichever choice is made, it does not affect how the memory is perceived by the rest of the system.

Furthermore, it should be understood that with replacement of VLT memory for DRAM memory, DDR controllers with requirements different from LPDDR4 may also be adapted and used with VLT memory as described above.

This description of the invention has been presented for the purposes of illustration and description. It is not intended to be exhaustive or to limit the invention to the precise form described, and many modifications and variations are possible in light of the teaching above. The embodiments were chosen and described in order to best explain the principles of the invention and its practical applications. This description will enable others skilled in the art to best utilize and practice the invention in various embodiments and with various modifications as are suited to a particular use. The scope of the invention is defined by the following claims.

The invention claimed is:

1. A memory system comprising:
a plurality of memory integrated circuits, each memory integrated circuit having:
a plurality of parallel bit lines in a first direction and a plurality of parallel word lines in a second direction perpendicular to the first direction;
a plurality of thyristor memory cells, each thyristor memory cell at the intersection of a bit line and a word line, and formed by semiconductor layers vertically arranged in a semiconductor substrate, the semiconductor layers doped with alternating P and N-type dopants, a top semiconductor layer connected to a bit or word lines, a bottom semiconductor layer connected to the other of the bit or word lines; and
each of the bit lines connected to an input of a multiplexer, the output of the multiplexer coupled to a sense amplifier for reading the value of a bit stored in a selected thyristor memory cell; and
a memory controller controlling the transfer of data to and from the plurality of memory integrated circuits according to DDR requirements;
whereby the memory system can transfer data at high-speed.

2. The memory system of claim 1 wherein each memory integrated circuits comprises at least 8 G (2³³) memory cells.

3. The memory system of claim 1 wherein each memory integrated circuit comprises a plurality of MATs (Memory Array Tiles), each MAT having at least 8M (2²³) thyristor memory cells.

4. The memory system of claim 3 wherein each MAT is arranged as 2¹¹ cells wide and 2¹² cells deep.

5. The memory system of claim 3 wherein the thyristor memory cells of the memory integrated circuits are arranged in banks, each bank having 64 MATs.

6. The memory system of claim 3 wherein each MAT comprises 512 sense amps supporting the 4K (2¹²) bit lines, each of the sense amps having an input connected to a multiplexer, the multiplexer having inputs connected to 8 bit lines.

7. The memory system of claim 1 wherein each memory integrated circuit is formed by 2X-nm process technology.

8. The memory system of claim 1 wherein the memory controller controls the transfer of data to and from the at least one memory integrated circuit according to LPDDR4 requirements.

9. The memory system of claim 8 wherein the memory controller operates with no logic states for refresh operations in the plurality of memory integrated circuits.

10. For a memory system having a plurality of memory integrated circuits, each memory integrated circuit having a plurality of thyristor memory cells, each thyristor memory cell at the intersection of a bit line and a word line, and formed by semiconductor layers vertically arranged in a semiconductor substrate, the semiconductor layers doped with alternating P and N-type dopants, a top semiconductor layer connected to a bit or word lines, a bottom semiconductor layer connected to the other of the bit or word lines, each of the bit lines connected to an input of a multiplexer, the output of the multiplexer coupled to a sense amplifier for reading the value of a bit stored in a selected thyristor memory cell, a memory controller controlling the transfer of data to and from the plurality of memory integrated circuits according to DDR requirements, the memory controller operating with no logic states for refresh operations in the plurality of memory integrated circuits.

11. The memory controller of claim 10 wherein the DDR requirements comprise LPDDR4 requirements.
